(19) United States
(12) Patent Application Publication
(10) Pub. No.: US 2025/0329640 A1
(43) Pub. Date: Oct. 23, 2025

(54) SEMICONDUCTOR INTEGRATED CIRCUIT DEVICE

(71) Applicant: Socionext Inc., Kanagawa (JP)

(72) Inventor: Hideyuki KOMURO, Yokohama-shi (JP)

(21) Appl. No.: 19/255,659

(22) Filed: Jun. 30, 2025

Related U.S. Application Data
(63) Continuation of application No. PCT/JP2024/001669, filed on Jan. 22, 2024.

(30) Foreign Application Priority Data
Jan. 31, 2023 (JP) 2023-013387

(51) Int. Cl. H01L 23/528; H10D 84/83; H10D 89/10

(52) U.S. Cl. CPC H01L 23/528; H10D 84/832; H10D 89/10

(57) ABSTRACT

In a semiconductor integrated circuit device, a terminal cell is placed at an end of a cell row. A cell having a logical function includes: an active region including a first nanosheet extending in the X direction; and a first power line formed on the back side of a transistor and extending in the X direction. The terminal cell includes: an active region including a second nanosheet extending in the X direction; and a second power line extending in the X direction. The second nanosheet is the same in width and position in the Y direction as the first nanosheet, and the second power line is the same in width and position in the Y direction as the first power line.

### CROSS-REFERENCE TO RELATED APPLICATIONS

This is a continuation of International Application No. PCT/JP2024/001669 filed on Jan. 22, 2024, which claims priority to Japanese Patent Application No. 2023-013387 filed on Jan. 31, 2023. The entire disclosures of these applications are incorporated by reference herein.

### BACKGROUND

The present disclosure relates to a semiconductor integrated circuit device.

As a method for forming a semiconductor integrated circuit on a semiconductor substrate, a standard cell method is known. The standard cell method is a method in which basic units (e.g., inverters, latches, flipflops, and full adders) having specific logical functions are prepared in advance as standard cells, and a plurality of such standard cells are placed on a semiconductor substrate and connected through interconnects, whereby an LSI chip is designed.

Also, as for a transistor, which is a basic constituent of an LSI, improvement in integration degree, reduction in operating voltage, and improvement in operating speed have been achieved by reducing (scaling) the gate length. In recent years, however, increase in off current due to excessive scaling and the resulting significant increase in power consumption have raised a problem. To solve this problem, three-dimensional transistors, of which the transistor structure has changed from the conventional planar structure to a three-dimensional structure, have been vigorously studied. A nanosheet FET is one example of such three-dimensional transistors.

WO 2020/170715 (Patent Document 1) discloses a structure of a terminal cell used for terminating a circuit block constituted by standard cells using complementary FETs (CFETs). The “terminal cell” is a cell used for terminating a circuit block without contributing to any logical function of the circuit block.

US Patent Application Publication No. 2021/375853 (Patent Document 2) discloses, for further higher integration, a technique of providing interconnects on the back of a substrate right under transistors and connecting the sources/drains of the transistors to the interconnects.

As of today, no concrete examination has been made on the layout of terminal cells in a circuit block constituted by standard cells having interconnects right under transistors.

An objective of the present disclosure is presenting a layout of a semiconductor integrated circuit device including terminal cells having interconnects right under transistors.

### SUMMARY

According to the first mode of the disclosure, a semiconductor integrated circuit device includes: a plurality of cell rows each including a plurality of standard cells arranged in a first direction, wherein a first cell row as one of the plurality of cell rows includes a first standard cell having a logical function, and a second standard cell placed at an end of the first cell row in the first direction, adjoining the first standard cell, and having no logical function, the first standard cell includes a first active region forming a channel, source, and drain of a first transistor of a first conductivity type, and including a first nanosheet extending in the first direction as the channel, a first gate interconnect extending in a second direction perpendicular to the first direction and intersecting with the first nanosheet at right angles in planar view, and a first power line formed on the back side of the first transistor, extending in the first direction, having an overlap with the first active region in planar view, and supplying a first power supply voltage, the second standard cell includes a second active region including a second nanosheet extending in the first direction, a second gate interconnect extending in the second direction and intersecting with the second nanosheet at right angles in planar view, and a second power line formed in a same interconnect layer as the first power line, extending in the first direction, having an overlap with the second active region in planar view, and supplying the first power supply voltage, the second nanosheet is the same in width and position in the second direction as the first nanosheet, and the second power line is the same in width and position in the second direction as the first power line.

According to the above mode, in the first cell row constituting the semiconductor integrated circuit device, a second standard cell having no logical function is placed at an end in a first direction in which standard cells are arranged. The second standard cell is adjacent to a first standard cell having a logical function. The first standard cell includes: a first active region including a first nanosheet that extends in the first direction and is to be the channel of a transistor; a first gate interconnect extending in a second direction perpendicular to the first direction; and a first power line formed on the back side of the transistor and extending in the first direction. The second standard cell includes: a second active region including a second nanosheet extending in the first direction; a second gate interconnect extending in the second direction; and a second power line formed in the same interconnect layer as the first power line and extending in the first direction. The second nanosheet is the same in width and position in the second direction as the first nanosheet, and the second power line is the same in width and position in the second direction as the first power line. It is therefore possible to reduce variations in the finished shape of the layout pattern of the first standard cell, whereby reduction in the manufacturing variations, improvement in the yield, and improvement in the reliability, of the semiconductor integrated circuit device can be achieved.

According to the second mode of the disclosure, a semiconductor integrated circuit device includes: a plurality of cell rows each including a plurality of standard cells arranged in a first direction, wherein the plurality of cell rows include a first cell row, and a second cell row located on an end of the plurality of cell rows in a second direction perpendicular to the first direction, and adjoining the first cell row, the first cell row includes a first standard cell having a logical function, the second cell row includes a second standard cell located adjacent to the first standard cell and having no logical function, the first standard cell includes a first active region forming a channel, source, and drain of a first transistor of a first conductivity type, and including a first nanosheet extending in the first direction as the channel, a first gate interconnect extending in the second direction and intersecting with the first nanosheet at right angles in planar view, and a first power line formed on the back side of the first transistor, extending in the first direction, having an overlap with the first active region in planar view, and supplying a first power supply voltage, the second standard cell includes a second active region including a second nanosheet extending in the first direction, a second gate interconnect extending in the second direction and intersecting with the second nanosheet at right angles in planar view, and a second power line formed in a same interconnect layer as the first power line, extending in the first direction, having an overlap with the second active region in planar view, and supplying the first power supply voltage, the second nanosheet is the same in width in the second direction and a distance from a boundary between the first standard cell and the second standard cell as the first nanosheet, and the second power line is the same in width in the second direction as the first power line.

According to the above mode, a second standard cell having no logical function is placed in a second cell row located on an end in a second direction perpendicular to a first direction in which standard cells are arranged, among a plurality of cell rows constituting the semiconductor integrated circuit device. The second standard cell is adjacent to a first standard cell having a logical function. The first standard cell includes: a first active region including a first nanosheet that extends in the first direction and is to be the channel of a transistor; a first gate interconnect extending in the second direction; and a first power line formed on the back side of the transistor and extending in the first direction. The second standard cell includes: a second active region including a second nanosheet extending in the first direction; a second gate interconnect extending in the second direction; and a second power line formed in the same interconnect layer as the first power line and extending in the first direction. The second nanosheet is the same in width in the second direction and the distance from the boundary between the first and second standard cells as the first nanosheet, and the second power line is the same in width in the second direction as the first power line. It is therefore possible to reduce variations in the finished shape of the layout pattern of the first standard cell, whereby reduction in the manufacturing variations, improvement in the yield, and improvement in the reliability, of the semiconductor integrated circuit device can be achieved.

According to the present disclosure, in a semiconductor integrated circuit device using standard cells having interconnects right under transistors, reduction in manufacturing variations, improvement in yield, and improvement in reliability can be achieved.

### BRIEF DESCRIPTION OF THE DRAWINGS

FIG. 1 is a plan view showing a layout structure of a circuit block of a semiconductor integrated circuit device according to an embodiment.

FIG. 2 is a plan view showing a layout structure of standard cells according to the first embodiment.

FIGS. 3A and 3B are cross-sectional views of the configuration of FIG. 2.

FIGS. 4A and 4B show another configuration example.

FIGS. 5A to 5C are plan views showing layout structures of terminal cells according to Alteration 1 of the first embodiment.

FIG. 6 is a plan view showing a layout structure of a terminal cell according to Alteration 2 of the first embodiment.

FIG. 7 is a cross-sectional view of the configuration of FIG. 6.

FIG. 8 is a plan view showing another layout structure of the terminal cell according to Alteration 2 of the first embodiment.

FIG. 9 is a plan view showing a layout structure of a terminal cell according to Alteration 3 of the first embodiment.

FIG. 10 is a plan view showing a layout structure of standard cells according to the second embodiment.

FIG. 11 is a plan view showing a layout structure of a terminal cell according to an alteration of the second embodiment.

### DETAILED DESCRIPTION

Embodiments of the present disclosure will be described hereinafter with reference to the accompanying drawings. In the following embodiments, it is assumed that the semiconductor integrated circuit device includes a plurality of standard cells (hereinafter simply called cells as appropriate), and at least some of the standard cells include nanosheet field effect transistors (FETs). The nanosheet FET is a FET using a thin sheet (nanosheet) through which a current flows. Such a nanosheet is formed of silicon, for example. Note however that, in the present disclosure, the transistors included in the standard cells are not limited to nanosheet FETs.

Note that, in the plan views and the cross-sectional views in the following embodiments, illustration of various insulating films may be omitted. As used herein, “VDD” and “VSS” refer to the power supply voltages or the power supplies themselves. Also, as used herein, an expression indicating that sizes such as widths are identical, like the “same wiring width,” is to be understood as including a range of manufacturing variations.

### (Configuration of Circuit Block)

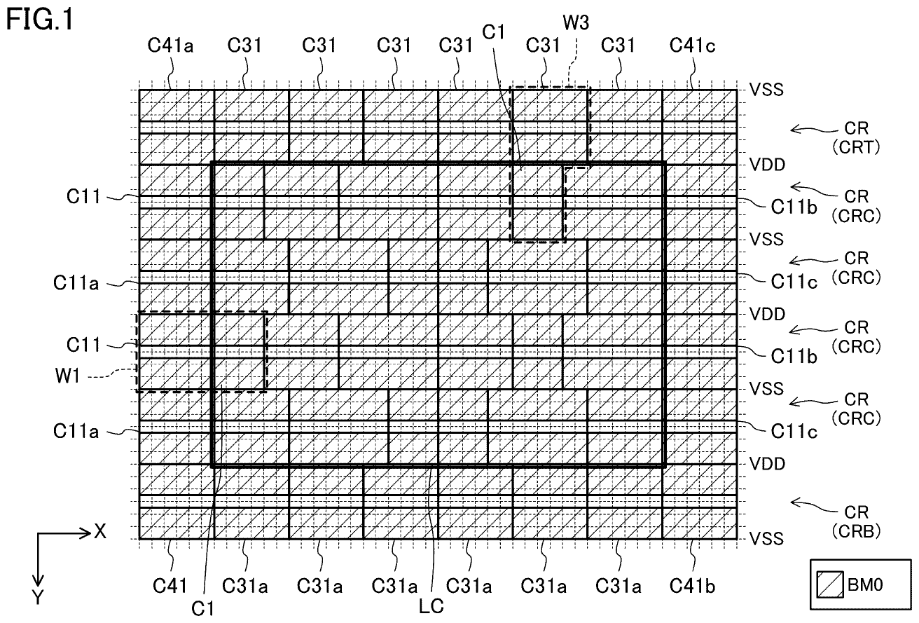

FIG. 1 is a plan view showing a layout example of a circuit block using standard cells. In FIG. 1, only power lines provided in standard cells are illustrated, omitting the other components. In the following embodiments, power lines are formed in a backside metal 0 (BM0) layer that is an interconnect layer provided on the back of a semiconductor chip in which transistors are formed.

Note that, in the plan views such as FIG. 1, the horizontal direction in the figure is hereinafter referred to as an X direction (corresponding to the first direction), the vertical direction in the figure as a Y direction (corresponding to the second direction), and the direction perpendicular to the substrate plane as a Z direction. Also, the dot lines running horizontally and vertically in the plan views such as FIG. 1 represent grid lines used for placement of components at design time. The grid lines are arranged at an equal spacing in the X direction and also arranged at an equal spacing in the Y direction. The grid spacings in the X direction and the Y direction may be the same or different from each other.

Also, hereinafter, the same components are denoted by the same reference characters, and description of such components may not be repeated.

In the layout of FIG. 1, a plurality of cells arranged in the X direction constitute a cell row CR, and a plurality of cell rows CR (six rows in FIG. 1) are arranged in the Y direction. Power lines are formed on both ends of the cells in the Y direction, through which power supply potentials VDD and VSS are supplied to the cells from outside. The cell rows are placed in a vertically flipped position every other row so that the power line supplying VDD and the power line supplying VSS are flipped in the Y direction every other cell row.

The plurality of cells include cells having logical functions, such as NAND gates and NOR gates (including inverter cells C1 having the logical function of inverters to be described later), and terminal cells having no logical function.

The “terminal cells” as used herein refer to cells placed at terminals of the circuit block without contributing to any logical function of the circuit block. The “terminals of the circuit block” as used herein refer to both ends (in the X direction in this case) of the cell rows constituting the circuit block and the uppermost and lowermost rows (cell rows on both ends in the Y direction in this case) of the circuit block. That is, the “terminal cells” are placed at both ends of the cell rows in the X direction and in the cell rows on both ends in the Y direction, which are the terminals of the circuit block. By placing terminal cells, variations in the finished shape of the layout pattern of cells located inward with respect to the terminal cells in the circuit block can be reduced, whereby reduction in the manufacturing variations, improvement in the yield, and improvement in the reliability, of the semiconductor integrated circuit device can be achieved.

In this embodiment, dummy gate interconnects are placed in the terminal cells. The “dummy gate interconnects” as used herein refer to a gate interconnect forming no transistor and a gate interconnect forming a transistor that does not contribute to the logical function of the circuit.

In the layout of FIG. 1, a rectangular logical unit LC that includes logic cells having logical functions and implements a circuit function is placed in the center of the circuit block. A terminal cell unit is formed along the periphery of the circuit block so as to surround the logical unit LC.

In FIG. 1, the inverter cells C1 are placed in the logical unit LC, and terminal cells C11, C11a to C11c, C31, C31a, C41, and C41a to C41c are placed in the terminal cell unit. The terminal cells C11a, C11b, and C11c are ones flipped from the terminal cells C11 in the Y direction, in the X direction, and in the X and Y directions, respectively. The terminal cells C31a are ones flipped from the terminal cells C31 in the Y direction. The terminal cells C41 and C41a to C41c are cells similar in configuration to the terminal cells C11 and C11a to C11c, respectively. That is, the terminal cells C41a, C41b, and C41c are ones flipped from the terminal cells C41 in the Y direction, in the X direction, and in the X and Y directions, respectively.

Specifically, in a cell row CRT that is the uppermost row of the circuit block in the Y direction, the terminal cell C41a is placed at the left end in the figure, the terminal cell C41c is placed at the right end in the figure, and a plurality of terminal cells C31 are placed in line in the X direction between the terminal cells C41a and C41c. In a cell row CRB that is the lowermost row of the circuit block in the Y direction, the terminal cell C41 is placed at the left end in the figure, the terminal cell C41b is placed at the right end in the figure, and a plurality of terminal cells C31a are placed in line in the X direction between the terminal cells C41 and C41b. Between the cell rows CRT and CRB, cell rows CRC having the terminal cell C11 at the left end in the figure and the terminal cell C11b at the right end in the figure and cell rows CRC having the terminal cell C11a at the left end in the figure and the terminal cell C11c at the right end in the figure are placed alternately in the Y direction. Between the terminal cells C11 and C11b, and between the terminal cells C11a and C11c, cells constituting the logical unit LC are placed. Therefore, in FIG. 1, the terminal cells C11 and other terminal cells similar in configuration are placed along the left and right ends of the logical unit LC in the figure, and the terminal cells C31 and other terminal cells similar in configuration are placed along the upper and lower ends of the logical unit LC in the figure. Also, in the four corners of the circuit block, the terminal cell C41 and other terminal cells similar in configuration are placed.

### First Embodiment

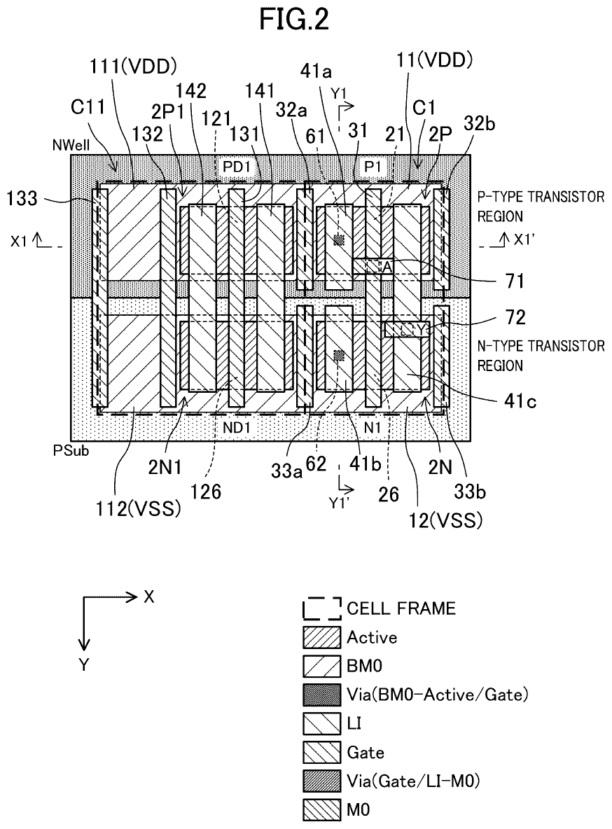

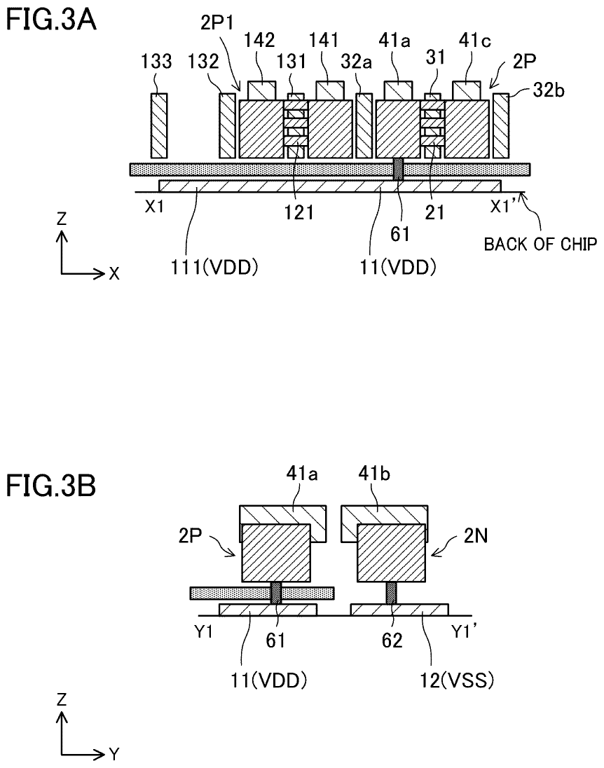

FIG. 2 is an enlarged plan view of part W1 in FIG. 1, showing a layout structure of standard cells in this embodiment. FIGS. 3A-3B are cross-sectional views of FIG. 2, where FIG. 3A shows a cross section taken along line X1-X1′ in FIG. 2, and FIG. 3B shows a cross section taken along line Y1-Y1′ in FIG. 2.

As shown in FIGS. 1, 2, 3A, and 3B, the inverter cell C1 is placed at the left end of the logical unit LC in the figure, and the terminal cell C11 is adjacently placed on the left side of the inverter cell C1.

### (Configuration of Inverter Cell)

As shown in FIG. 2, in the inverter cell C1, power lines 11 and 12 extending in the X direction are laid on the ends in the Y direction. The power lines 11 and 12 are formed in the BM0 layer that is an interconnect layer provided on the back of the semiconductor chip in which transistors are formed. The power line 11 supplies the power supply voltage VDD, and the power line 12 supplies the power supply voltage VSS. The power lines 11 and 12 are shared with other cells in the cell row including the inverter cell C1, forming power lines extending in the X direction. Also, the power lines 11 and 12 are shared between cell rows adjacent in the Y direction.

An active region 2P forming the channel, source, and drain of a p-type transistor is formed in a p-type transistor region on an n-type well (NWell). The active region 2P overlaps the power line 11 in planar view.

A p-type transistor P1 is formed in the p-type transistor region. The transistor P1 includes nanosheets 21 having a structure of three sheets lying one above another and extending in the X direction, as its channel. That is, the transistor P1 is a nanosheet FET. In the active region 2P, the portion that is to be the source of the transistor P1 is connected to the power line 11 through a via 61.

An active region 2N forming the channel, source, and drain of an n-type transistor is formed in an n-type transistor region on a p-type substrate (PSub). The active region 2N overlaps the power line 12 in planar view. Note that the n-type transistor region may be formed on a p-type well.

An n-type transistor N1 is formed in the n-type transistor region. The transistor N1 includes nanosheets 26 having a structure of three sheets lying one above another and extending in the X direction, as its channel. That is, the transistor N1 is a nanosheet FET. In the active region 2N, the portion that is to be the source of the transistor N1 is connected to the power line 12 through a via 62.

Note that, in the active regions, the portions that are to be the sources and the drains on the sides of the nanosheets are formed by epitaxial growth from the nanosheets, for example.

A gate interconnect 31 extends in the Y direction from the p-type transistor region over to the n-type transistor region. The gate interconnect 31 surrounds the peripheries of the nanosheets 21 of the transistor P1 and the nanosheets 26 of the transistor N1 in the Y and Z directions via gate insulating films (not shown). The gate interconnect 31 corresponds to the gates of the transistors P1 and N1.

In the p-type transistor region, dummy gate interconnects 32a and 32b are formed on the side portions of the cell frame in the X direction. In the n-type transistor region, dummy gate interconnects 33a and 33b are formed on the side portions of the cell frame in the X direction. The dummy gate interconnects 32a and 33a are shared with a cell placed on the left in the figure (the cell C11 in FIG. 2), and the dummy gate interconnects 32b and 33b are shared with a cell placed on the right in the figure.

The dummy gate interconnects 32a and 33a, the gate interconnect 31, and the dummy gate interconnects 32b and 33b are arranged at the same pitch in the X direction. Also, the gate interconnect 31 and the dummy gate interconnects 32a, 32b, 33a, and 33b have the same width in the X direction.

Local interconnects 41a, 41b, and 41c extending in the Y direction are formed in a local interconnect layer. Note that the local interconnects are represented as LI in the figures. The local interconnect 41a is connected to the portion that is to be the source of the transistor P1 in the active region 2P. The local interconnect 41b is connected to the portion that is to be the source of the transistor N1 in the active region 2N. The local interconnect 41c extends from the p-type transistor region over to the n-type transistor region, and is connected to the portion that is to be the drain of the transistor P1 in the active region 2P and the portion that is to be the drain of the transistor N1 in the active region 2N.

Metal interconnects 71 and 72 extending in the X direction are formed in an M0 interconnect layer that is a metal interconnect layer located above the local interconnect layer. The metal interconnect 71 is connected to the gate interconnect 31 through a via. The metal interconnect 72 is connected to the local interconnect 41c through a via. The metal interconnect 71 corresponds to an input node A, and the metal interconnect 72 corresponds to an output node Y.

As described above, the inverter cell C1, having the p-type transistor P1 and the n-type transistor N1, implements an inverter circuit having the input A and the output Y. That is, the inverter cell C1 is a standard cell having a logical function.

### (Configuration of Terminal Cell)

As shown in FIG. 1, the terminal cell C11 is placed at the left end of the cell row CRC in the X direction.

As shown in FIG. 2, in the terminal cell C11, power lines 111 and 112 extending in the X direction are laid on the ends in the Y direction. The power lines 111 and 112 are formed in the BM0 layer that is an interconnect layer provided on the back of the semiconductor chip in which transistors are formed. The power line 111 supplies the same power supply voltage VDD as the power line 11, and the power line 112 supplies the same power supply voltage VSS as the power line 12. The power line 111 is formed at the same position in the Y direction, and has the same width, as the power line 11. The power line 112 is formed at the same position in the Y direction, and has the same width, as the power line 12.

An active region 2P1 forming the channel, source, and drain of a p-type transistor is formed in the p-type transistor region on the n-type well (NWell). The active region 2P1 overlaps the power line 111 in planar view. A p-type transistor PD1 as a dummy transistor is formed in the p-type transistor region. The transistor PD1 includes nanosheets 121 having a structure of three sheets lying one above another and extending in the X direction, as its channel. The nanosheets 121 are the same in position and width in the Y direction as the nanosheets 21 in the inverter cell C1.

An active region 2N1 forming the channel, source, and drain of an n-type transistor is formed in the n-type transistor region on the p-type substrate (PSub). The active region 2N1 overlaps the power line 112 in planar view. An n-type transistor ND1 as a dummy transistor is formed in the n-type transistor region. The transistor ND1 includes nanosheets 126 having a structure of three sheets lying one above another and extending in the X direction, as its channel. The nanosheets 126 are the same in position and width in the Y direction as the nanosheets 26 in the inverter cell C1.

A dummy gate interconnect 131 extends in the Y direction from the p-type transistor region over to the n-type transistor region. The dummy gate interconnect 131 surrounds the peripheries of the nanosheets 121 of the transistor PD1 and the nanosheets 126 of the transistor ND1 in the Y and Z directions via gate insulating films (not shown).

On the left side of the dummy gate interconnect 131 in the figure, two dummy gate interconnects 132 and 133 extend in the Y direction from the p-type transistor region over to the n-type transistor region. The dummy gate interconnect 133 is placed on the left end of the terminal cell C11.

Local interconnects 141 and 142 extending in the Y direction are formed in the local interconnect layer. The local interconnect 141 extends from the p-type transistor region over to the n-type transistor region, and is connected to the portion that is to be the drain of the transistor PD1 in the active region 2P1 and the portion that is to be the drain of the transistor ND1 in the active region 2N1. The local interconnect 142 extends from the p-type transistor region over to the n-type transistor region, and is connected to the portion that is to be the source of the transistor PD1 in the active region 2P1 and the portion that is to be the source of the transistor ND1 in the active region 2N1.

In the terminal cell C11, none of the dummy gate interconnects 131, 132, and 133 and the local interconnects 141 and 142 are connected to other interconnects.

As described above, the terminal cell C11 does not have any operating transistor. That is, the terminal cell C11 is a standard cell having no logical function.

As shown in FIGS. 2, 3A, and 3B, the dummy gate interconnects 131, 132, and 133 of the terminal cell C11 are formed at the same position in the Y direction, and have the same length, as the gate interconnect 31 of the inverter cell C1. Also, the dummy gate interconnect 133, the dummy gate interconnect 132, the dummy gate interconnect 131, the dummy gate interconnects 32a and 33a, the gate interconnect 31, and the dummy gate interconnects 32b and 33b are arranged at the same pitch in the X direction, and the positions of both ends of these interconnects in the Y direction are the same.

The local interconnects 141 and 142 of the terminal cell C11 are the same in the positions of both ends in the Y direction as the local interconnects 41a and 41b and the local interconnect 41c of the inverter cell C1. Also, the local interconnect 142, the local interconnect 141, the local interconnects 41a and 41b, and the local interconnect 41c are arranged at the same pitch in the X direction.

With the above configuration, the inverter cell C1 having a logical function and the terminal cell C11 having no logical function are placed in the cell row CRC. The terminal cell C11 is placed at the left end of the cell row CRC. The nanosheets 121 and 126 of the terminal cell C11 are the same in width and position in the Y direction as the nanosheets 21 and 26 of the inverter cell C1. Also, the power lines 111 and 112 of the terminal cell C11 are the same in width and position in the Y direction as the power lines 11 and 12 of the inverter cell C1. It is therefore possible to reduce variations in the finished shape of the layout pattern of cell placed inward with respect to the terminal cells in the circuit block, whereby reduction in the manufacturing variations, improvement in the yield, and improvement in the reliability, of the semiconductor integrated circuit device can be achieved.

Also, by providing the dummy gate interconnects and the local interconnects in the terminal cell, the gate interconnects including the dummy gate interconnects and the local interconnects are arranged regularly. It is therefore possible to reduce variations in the finished shape of the layout pattern of cells placed inward with respect to the terminal cells in the circuit block, whereby reduction in the manufacturing variations, improvement in the yield, and improvement in the reliability, of the semiconductor integrated circuit device can be achieved.

Also, the dummy gate interconnects 131 to 133 of the terminal cell C11 are formed with the same length in the Y direction as the gate interconnect 31 of the inverter cell C1. It is therefore possible to reduce variations in the finished shape of the layout pattern, whereby the manufacturing variations of the semiconductor integrated circuit device can be reduced.

Moreover, the local interconnects 141 and 142 of the terminal cell C11 are placed so that the positions of both ends in the Y direction are the same as those of the local interconnects 41a and 41b and the local interconnect 41c of the inverter cell C1. With this, since the distance from the logical unit LC to the nearest local interconnect can be made constant, the performance predictability of cells placed in the logical unit LC can be improved. Also, variations in the finished shape of the layout pattern of cells placed inward with respect to the terminal cells in the circuit block can be reduced, whereby reduction in the manufacturing variations, improvement in the yield, and improvement in the reliability, of the semiconductor integrated circuit device can be achieved.

While three dummy gate interconnects (131 to 133) and two local interconnects (141 and 142) are placed in the terminal cell C11 in the configuration of FIGS. 2, 3A, and 3B, the numbers of dummy gate interconnects and local interconnects placed in the terminal cell C11 are not limited to these. In the terminal cell C11, however, dummy gate interconnects and local interconnects of the numbers required to reduce variations in the finished dimensions of the ends of the logical unit are to be placed. The cell width (size in the X direction) of the terminal cell C11 may be changed depending on the numbers of dummy gate interconnects and local interconnects placed in the terminal cell C11.

While the dummy gate interconnects 131 to 133 of the terminal cell C11 are formed with the same length in the Y direction as the gate interconnect 31 of the inverter cell C1 in the above description, the configuration is not limited to this, However, by forming these interconnects with the same length in the Y direction, the manufacturing variations of the circuit block can be more reduced.

Also, while the local interconnects 141 and 142 of the terminal cell C11 are placed so that the positions of both ends in the Y direction are the same as those of the local interconnects 41a and 41b and the local interconnect 41c of the inverter cell C1 in the above description, the configuration is not limited to this, However, by placing these interconnects so that the positions of both ends in the Y direction are the same, the manufacturing variations of the circuit block can be more reduced.

In FIG. 1, the terminal cell C11b flipped in the X direction from the terminal cell C11 is placed at the right end of the cell row CRC in the figure.

While the power lines 11, 12, 111, and 112 are formed in the interconnect layer provided on the back of the semiconductor chip in the above description, the configuration is not limited to this. According to the present disclosure, it is only required for the power lines to be formed on the back side of the transistors. The “back side of the transistors” as used herein refers to the side, with respect to the transistors, opposite to the side on which the local interconnects, the metal interconnects, and the like connected to the transistors are stacked one upon another.

The power lines 11, 12, 111, and 112 may be formed in a plurality of interconnect layers.

### OTHER CONFIGURATION EXAMPLE

The power lines on the back side of the transistors described above may also be formed using a semiconductor chip other than the semiconductor chip in which the transistors are formed.

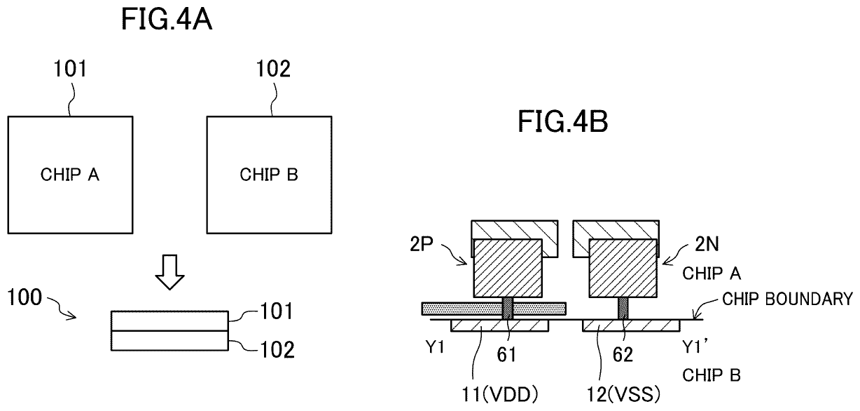

FIG. 4A shows another configuration example of the semiconductor integrated circuit device according to this embodiment. A semiconductor integrated circuit device 100 shown in FIG. 4A is constituted by a first semiconductor chip 101 (chip A) and a second semiconductor chip 102 (chip B) stacked one upon the other. In the chip A, the circuit block described above and the like are placed. In the chip B, power lines are formed in an interconnect layer provided on the surface. The chip B is bonded to the back of the chip A using bumps and the like.

FIG. 4B shows a cross section of this configuration example taken along line Y1-Y1′ in the inverter cell C1 in FIG. 2. As shown in FIG. 4B, the power line 11 supplying VDD and the power line 12 supplying VSS are formed in the interconnect layer provided on the surface of the chip B. The power line 11 is connected to the active region 2P in the chip A through the via 61, and the power line 12 is connected to the active region 2N in the chip A through the via 62. The power lines 111 and 112 of the terminal cell C11 are also formed in the interconnect layer provided on the surface of the chip B.

Note that, in this configuration example, also, the power lines 11, 12, 111, and 112 may be formed in a plurality of interconnect layers.

### (Alteration 1)

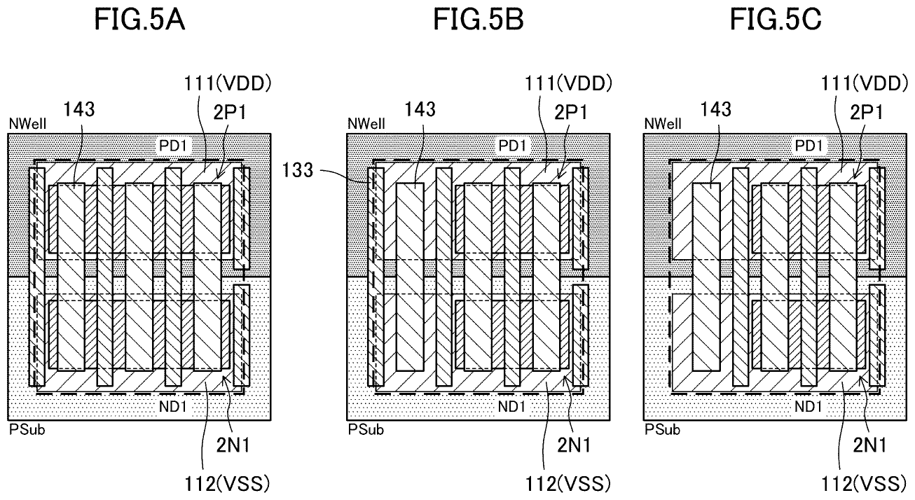

FIGS. 5A-5C are plan views showing layout configurations of alterations of the terminal cell. In the configuration of FIG. 5A, the active regions 2P1 and 2N1 further extend leftward in the figure, and a local interconnect 143 is added. In the configuration of FIG. 5B, there is no extension of the active regions 2P1 and 2N1, but the local interconnect 143 is added. In the configuration of FIG. 5C, the dummy gate interconnect 133 is deleted from the configuration of FIG. 5B.

Any of the terminal cells shown in FIGS. 5A to 5C may be placed instead of the terminal cell C11 in FIG. 2. Also, the active regions 2P1 and 2N1 may be omitted in the configurations of FIGS. 5A to 5C.

### (Alteration 2)

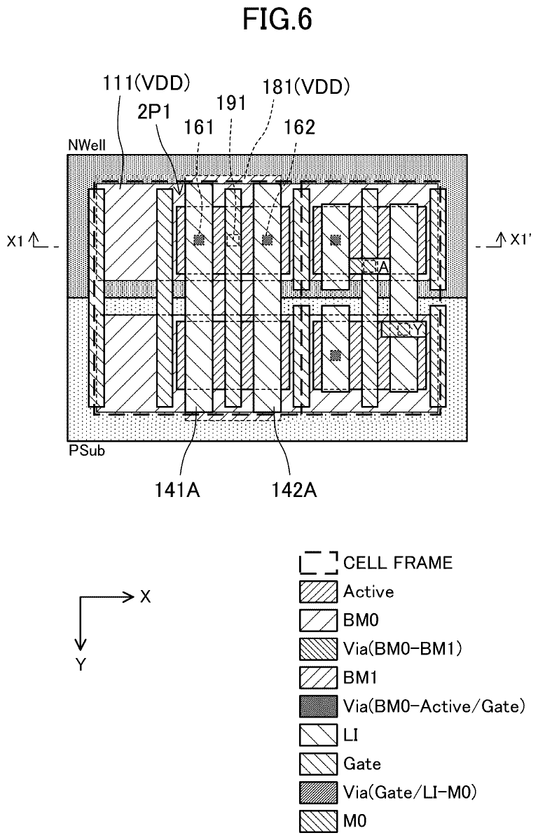

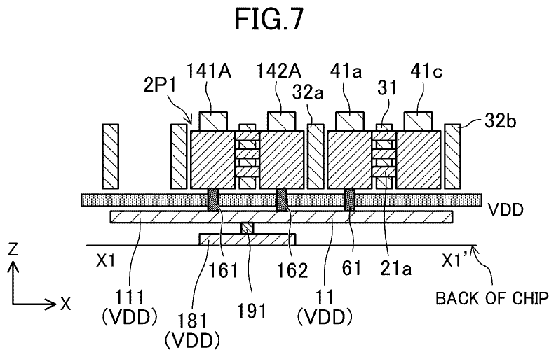

FIG. 6 is a plan view showing a layout structure of a terminal cell according to Alteration 2 of this embodiment. FIG. 7 is a cross-sectional view taken along line X1-X1′ in FIG. 6. In the configuration of FIGS. 6 and 7, a backside metal 1 (BM1) layer is formed, which is an interconnect layer provided on the back of the semiconductor chip in which transistors are formed. The BM1 layer is located under the BM0 layer, that is, located farther from the active region forming transistors than the BM0 layer.

In the BM1 layer, a power line 181 extending in the Y direction is formed. The power line 181 supplies VDD. In FIG. 6, for easy understanding of the figure, the power line 181 is shown to protrude from the cell frame. The power line 181 is connected to the power line 111 in the BM0 layer through a via 191.

By arranging such terminal cells of this alteration in line in Y direction, the power lines 181 in these terminal cells are contiguous with one another in the Y direction. With this, in the circuit block, a VDD power line extending in the Y direction is formed in the BM1 layer, whereby the power supply VDD can be strengthened.

Also, in the local interconnect layer, local interconnects 141A and 142A extend up to the cell ends in the Y direction. The local interconnects 141A and 142A are connected to the power line 111 in the BM0 layer through vias 161 and 162, respectively, and the active region 2P1.

By arranging the terminal cells of this alteration in line in Y direction, the local interconnects 141A and 142A are contiguous with each other in the Y direction. With this, in the circuit block, VDD power lines extending in the Y direction are formed in the local interconnect layer, whereby the power supply VDD can be strengthened.

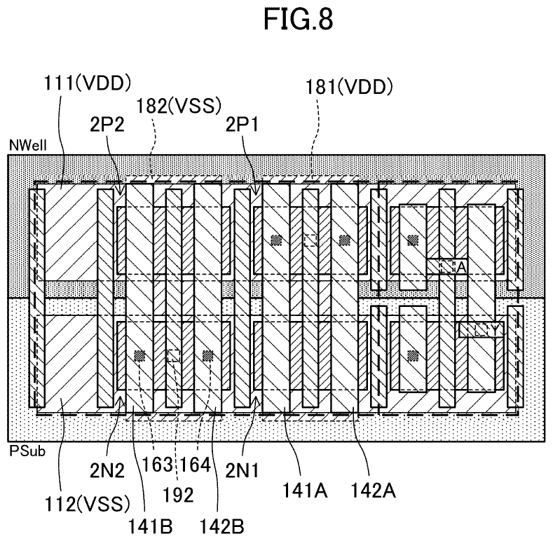

FIG. 8 is a plan view showing another layout structure of this alteration. In the configuration of FIGS. 6 and 7, the power supply VDD is strengthened by the power lines in the BM1 layer and the local interconnect layer. In the configuration of FIG. 8, however, both the power supply VDD and the power supply VSS are strengthened by the power lines in the BM1 layer and the local interconnect layer.

On the n-type well, an active region 2P2 is formed in addition to the active region 2P1. The active region 2P2 also overlaps the power line 111 in planar view. On the p-type substrate, an active region 2N2 is formed in addition to the active region 2N1. The active region 2N2 also overlaps the power line 112 in planar view.

In the BM1 layer, a power line 182 extending in the Y direction is formed. In FIG. 8, for easy understanding of the figure, the power lines 181 and 182 are shown to protrude from the cell frame. The power line 182 supplies VSS. The power line 182 is connected to the power line 112 in the BM0 layer through a via 192.

Also, in the local interconnect layer, local interconnects 141B and 142B extend up to the cell ends in the Y direction. The local interconnects 141B and 142B are connected to the power line 112 in the BM0 layer through vias 163 and 164, respectively, and the active region 2N2.

By arranging such terminal cells of this alteration in line in Y direction, the power lines 181 in these terminal cells are contiguous with one another in the Y direction, and also the power lines 182 in these terminal cells are contiguous with one another in the Y direction. With this, in the circuit block, a VDD power line and a VSS power line extending in the Y direction are formed in the BM1 layer, whereby the power supplies VDD and VSS can be strengthened.

Also, by arranging the terminal cells of this alteration in line in Y direction, the local interconnects 141A and 142A are contiguous with each other in the Y direction, and also the local interconnects 141B and 142B are contiguous with each other in the Y direction. With this, in the circuit block, VDD power lines and VSS power lines extending in the Y direction are formed in the local interconnect layer, whereby the power supplies VDD and VSS can be strengthened.

Note that, in this alteration, it is not necessarily required for the terminal cells themselves to have the power lines in the BM1 layer. That is, the power lines in the BM1 layer may be laid separately from the terminal cells and, after placement of the terminals cells, may be connected to the power lines of the terminal cells in the BM0 layer.

Also, while the power lines for strengthening the power supply are formed in both the BM1 layer and the local interconnect layer in this alteration, power lines may be formed in only either one of the BM1 layer and the local interconnect layer.

In this alteration, the BM0 layer and the BM1 layer may be formed using a semiconductor chip other than the semiconductor chip in which transistors are formed. Alternatively, while the BM0 layer is formed in the semiconductor chip in which transistors are formed, only the BM1 layer may be formed using a semiconductor chip other than the semiconductor chip in which transistors are formed.

### (Alteration 3)

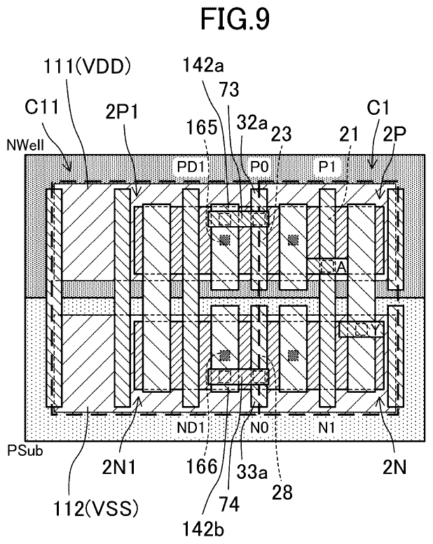

FIG. 9 is a plan view showing a layout structure of a terminal cell according to Alteration 3 of this embodiment. In the configuration of FIG. 9, the active regions 2P and 2N of the inverter cell C1 extend up to the left side position of the cell frame in the figure, and the active regions 2P1 and 2N1 of the terminal cell C11 extend up to the right side position of the cell frame in the figure. On the cell boundary between the inverter cell C1 and the terminal cell C11, nanosheets 23 are formed in the portion where the active regions 2P and 2P1 are in contact with each other, and nanosheets 28 are formed in the portion where the active regions 2N and 2N1 are in contact with each other. Like the nanosheets 21, the nanosheets 23 and 28 each have a structure of three sheets lying one above another and extend in the X direction.

The dummy gate interconnect 32a surrounds the peripheries of the nanosheets 23 in the Y and Z directions via gate insulating films (not shown). The dummy gate interconnect 33a surrounds the peripheries of the nanosheets 28 in the Y and Z directions via gate insulating films (not shown). With this, transistors P0 and N0 are formed on the cell boundary between the inverter cell C1 and the terminal cell C11.

In the terminal cell C11, the active region 2P1 is connected to the power line 111 through a via 165, and a local interconnect 142a is connected to the active region 2P1. VDD is therefore supplied to the local interconnect 142a. The active region 2N1 is connected to the power line 112 through a via 166, and a local interconnect 142b is connected to the active region 2N1. VSS is therefore supplied to the local interconnect 142b.

The dummy gate interconnect 32a is connected to the local interconnect 142a through an M0 interconnect 73. Therefore, since the gate of the transistor P0 is fixed to VDD, the transistor P0 is an off transistor. The dummy gate interconnect 33a is connected to the local interconnect 142b through an M0 interconnect 74. Therefore, since the gate of the transistor N0 is fixed to VSS, the transistor N0 is an off transistor. Thus, the transistors P0 and N0 have no influence on the logical operation of the semiconductor integrated circuit device.

### Second Embodiment

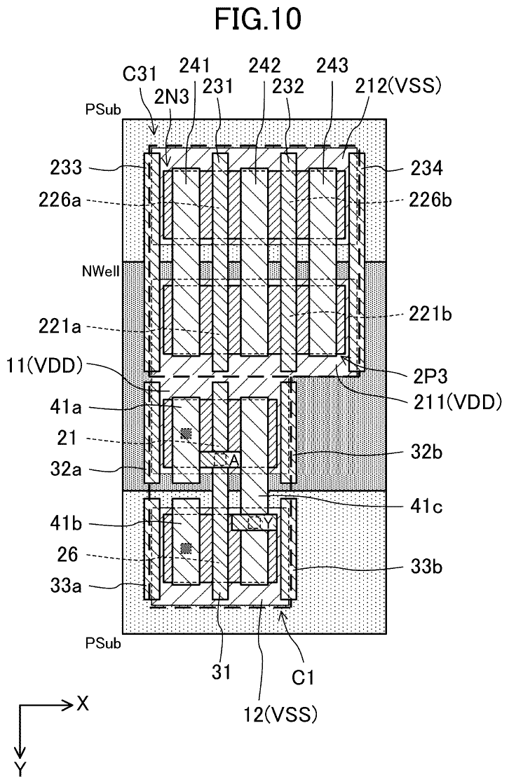

FIG. 10 is an enlarged plan view of part W3 in FIG. 1, showing a layout structure of standard cells according to this embodiment. As shown in FIG. 1, the terminal cell C31 is placed in the uppermost cell row CRT of the circuit block in the Y direction. Also, the terminal cell C31 is located adjacently on the upper side of the inverter cell C1 that is placed on the upper end of the logical unit LC in the figure.

As shown in FIG. 10, in the terminal cell C31, power lines 211 and 212 extending in the X direction are laid on the ends in the Y direction. The power lines 211 and 212 are formed in the BM0 layer that is the interconnect layer provided on the back of the semiconductor chip in which transistors are formed. The power line 211 supplies the same power supply voltage VDD as the power line 11. The power line 212 supplies the same power supply voltage VSS as the power line 12. The power line 211 is the same in width in the Y direction as the power line 11, and the power line 212 is the same in width in the Y direction as the power line 12.

In the terminal cell C31, an active region 2P3 forming the channel, source, and drain of a p-type transistor is formed in the p-type transistor region on the n-type well (NWell). The active region 2P3 overlaps the power line 211 in planar view. The active region 2P3 includes nanosheets 221a and 221b constituting dummy transistors. The nanosheets 221a and 221b each have a structure of three sheets lying one above another and extend in the X direction. The nanosheets 221a and 221b are the same in width in the Y direction as the nanosheets 21 of the inverter cell C1. Also, the nanosheets 221a and 221b are the same in the distance from the boundary between the inverter cell C1 and the terminal cell C31 as the nanosheets 21 of the inverter cell C1.

An active region 2N3 forming the channel, source, and drain of an n-type transistor is formed in the n-type transistor region on the p-type substrate (PSub). The active region 2N3 overlaps the power line 212 in planar view. The active region 2N3 includes nanosheets 226a and 226b constituting dummy transistors. The nanosheets 226a and 226b each have a structure of three sheets lying one above another and extend in the X direction. The nanosheets 226a and 226b are the same in width in the Y direction as the nanosheets 26 of the inverter cell C1.

Dummy gate interconnects 231 and 232 extend in the Y direction from the p-type transistor region over to the n-type transistor region. The dummy gate interconnect 231 surrounds the peripheries of the nanosheets 221a in the active region 2P3 and the nanosheets 226a in the active region 2N3 in the Y and Z directions via gate insulating films (not shown). The dummy gate interconnect 232 surrounds the peripheries of the nanosheets 221b in the active region 2P3 and the nanosheets 226b in the active region 2N3 in the Y and Z directions via gate insulating films (not shown).

On the left side of the dummy gate interconnect 231 in the figure, a dummy gate interconnect 233 extends in the Y direction from the p-type transistor region over to the n-type transistor region. The dummy gate interconnect 233 is formed on the left end of the terminal cell C31 in the figure. On the right side of the dummy gate interconnect 232 in the figure, a dummy gate interconnect 234 extends in the Y direction from the p-type transistor region over to the n-type transistor region. The dummy gate interconnect 234 is formed on the right end of the terminal cell C31 in the figure.

Local interconnects 241, 242, and 243 extending in the Y direction are formed in the local interconnect layer. The local interconnect 241, extending from the p-type transistor region over to the n-type transistor region, is connected to the portion between the dummy gate interconnects 231 and 233 in the active region 2P3 and the portion between the dummy gate interconnects 231 and 233 in the active region 2N3. The local interconnect 242, extending from the p-type transistor region over to the n-type transistor region, is connected to the portion between the dummy gate interconnects 231 and 232 in the active region 2P3 and the portion between the dummy gate interconnects 231 and 232 in the active region 2N3. The local interconnect 243, extending from the p-type transistor region over to the n-type transistor region, is connected to the portion between the dummy gate interconnects 232 and 234 in the active region 2P3 and the portion between the dummy gate interconnects 232 and 234 in the active region 2N3.

In the terminal cell C31, none of the dummy gate interconnects 231, 232, 233, and 234 and the local interconnects 241, 242 and 243 are connected to other interconnects.

As described above, the terminal cell C31 does not have any operating transistor. That is, the terminal cell C31 is a standard cell having no logical function.

As shown in FIG. 10, the nanosheets 221a and 226a in the terminal cell C31 are formed at the same position in the X direction as the nanosheets 21 and 26 in the inverter cell C1.

The dummy gate interconnects 231, 232, 233, and 234 in the terminal cell C31 are arranged at the same pitch in the X direction, and the positions of both ends of these interconnects in the Y direction are the same. Also, the dummy gate interconnect 231 in the terminal cell C31 is placed at the same position in the X direction as the gate interconnect 31 in the inverter cell C1. The dummy gate interconnect 232 in the terminal cell C31 is placed at the same position in the X direction as the dummy gate interconnects 32b and 33b in the inverter cell C1. The dummy gate interconnect 233 in the terminal cell C31 is placed at the same position in the X direction as the dummy gate interconnects 32a and 33a in the inverter cell C1.

The local interconnects 241, 242, and 243 in the terminal cell C31 are arranged at the same pitch in the X direction, and the positions of both ends of these interconnects in the Y direction are the same. Also, the local interconnect 241 in the terminal cell C31 is placed at the same position in the X direction as the local interconnects 41a and 41b in the inverter cell C1. The local interconnect 242 in the terminal cell C31 is placed at the same position in the X direction as the local interconnect 41c in the inverter cell C1.

With the above configuration, the terminal cell C31 having no logical function is placed in the uppermost row CRT of the circuit block adjacently to the inverter cell C1 having a logical function. The nanosheets 221a and 221b of the terminal cell C31 are the same in width in the Y direction, and the distance from the boundary between the inverter cell C1 and the terminal cell C31, as the nanosheets 21 of the inverter cell C1. Also, the power line 211 of the terminal cell C31 is the same in width in the Y direction as the power line 11 of the inverter cell C1. It is therefore possible to reduce variations in the finished shape of the layout pattern of cells placed inward with respect to the terminal cells in the circuit block, whereby reduction in the manufacturing variations, improvement in the yield, and improvement in the reliability, of the semiconductor integrated circuit device can be achieved.

Also, the terminal cell C31 includes the dummy transistors, the dummy gate interconnects, and the local interconnects. In the terminal cell C31, the nanosheets are formed at the same positions in the X direction as the nanosheets of the inverter cell C1, the dummy gate interconnects are placed at the same positions in the X direction as the gate interconnects of the inverter cell C1, and the local interconnects are placed at the same positions in the X direction as the local interconnects of the inverter cell C1. With this, the transistors including the dummy transistors, the gate interconnects including the dummy gate interconnects, and the local interconnects are arranged regularly. It is therefore possible to reduce variations in the finished shape of the layout pattern of cells placed inward with respect to the terminal cells in the circuit block, whereby reduction in the manufacturing variations, improvement in the yield, and improvement in the reliability, of the semiconductor integrated circuit device can be achieved.

Note that the cell width of the terminal cell C31 is not limited to that shown in FIG. 10.

Also, as shown in FIG. 1, in the lowermost cell row CRB of the circuit block, the terminal cells C31a that are ones flipped from the terminal cells C31 in the Y direction are placed.

In this embodiment, as in the first embodiment, the power lines 11, 12, 211, and 212 formed on the back side of transistors may be formed in the semiconductor chip in which the transistors are formed, or may be formed using a semiconductor chip other than the semiconductor chip in which the transistors are formed. Also, the power lines 11, 12, 211, and 212 may be formed in a plurality of interconnect layers.

### (Alteration)

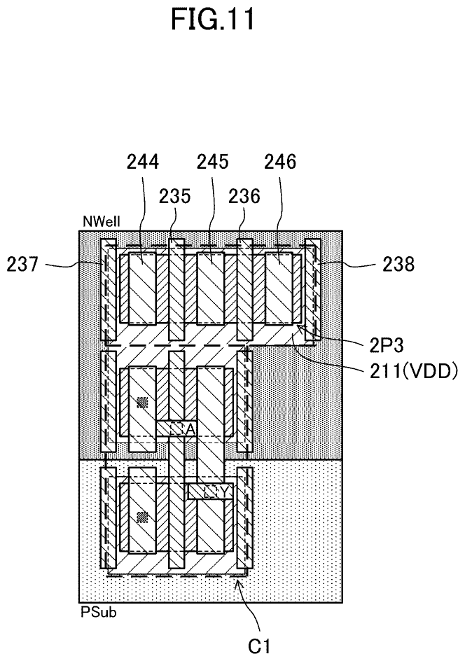

FIG. 11 is a plan view showing a layout structure of a terminal cell according to an alteration of this embodiment. In the configuration of FIG. 11, the upper VSS-side part of the terminal cell C31 in FIG. 10 is omitted. That is, the power line 212 and the active region 2N3 are omitted, the dummy gate interconnects 231 to 234 are replaced with short dummy gate interconnects 235 to 238, and the local interconnects 241 to 243 are replaced with short local interconnects 244 to 246.

In the configuration of FIG. 11, also, the power line 211, the active region 2P3, the dummy gate interconnects 235 to 238, and the local interconnects 244 to 246 are provided on the side facing the inverter cell C1 in the logical unit LC. It is therefore possible to reduce variations in the finished shape of the layout pattern of cells placed inward with respect to the terminal cells in the circuit block, whereby reduction in the manufacturing variations, improvement in the yield, and improvement in the reliability, of the semiconductor integrated circuit device can be achieved.

Note that, while the configuration of the VSS-side part is entirely omitted in the configurations of FIG. 11, the VSS-side part may be partly omitted.

The terminal cells placed in the corners of the circuit block are not limited to the terminal cells C41 and C41a to C41c. Any terminal cells described above may be placed in the corners of the circuit block.

While the circuit block is rectangular in FIG. 1, the shape is not limited to this. Also, while six cell rows are arranged in the circuit block in FIG. 1, the number of cell rows arranged in the circuit block is not limited to this.

While the nanosheets have the structure of three sheets lying one above another and the cross-sectional shape of the sheet structure is illustrated as a rectangle in the above embodiments, the number of nanosheets, and the cross-sectional shape, of the sheet structure are not limited to these.

While nanosheet FETs are used as the transistors in the above embodiments, the type of the transistors is not limited to this. For example, fin FETs or other types of transistors may be used.

According to the present disclosure, in a semiconductor integrated circuit device using standard cells having interconnects right under transistors, reduction in manufacturing variations, improvement in yield, and improvement in reliability can be achieved. It is therefore possible to achieve downsizing, and improvement in the performance, of the semiconductor integrated circuit device, for example.

1. A semiconductor integrated circuit device, comprising
a plurality of cell rows each including a plurality of standard cells arranged in a first direction,
wherein
a first cell row as one of the plurality of cell rows includes
a first standard cell having a logical function, and
a second standard cell placed at an end of the first cell row in the first direction, adjoining the first standard cell, and having no logical function,
the first standard cell includes
a first active region forming a channel, source, and drain of a first transistor of a first conductivity type, and including a first nanosheet extending in the first direction as the channel,
a first gate interconnect extending in a second direction perpendicular to the first direction and intersecting with the first nanosheet at right angles in planar view, and
a first power line formed on a back side of the first transistor, extending in the first direction, having an overlap with the first active region in planar view, and supplying a first power supply voltage,
the second standard cell includes
a second active region including a second nanosheet extending in the first direction,
a second gate interconnect extending in the second direction and intersecting with the second nanosheet at right angles in planar view, and
a second power line formed in a same interconnect layer as the first power line, extending in the first direction, having an overlap with the second active region in planar view, and supplying the first power supply voltage,
the second nanosheet is the same in width and position in the second direction as the first nanosheet, and
the second power line is the same in width and position in the second direction as the first power line.

2. The semiconductor integrated circuit device of claim 1, wherein
the second gate interconnect is the same in length and position in the second direction as the first gate interconnect.

3. The semiconductor integrated circuit device of claim 1, comprising
a third power line formed in an interconnect layer located below the first and second power lines, extending in the second direction, and supplying the first power supply voltage, wherein
the third power line is connected to the second power line through a via.

4. The semiconductor integrated circuit device of claim 1, wherein
the second standard cell includes
a first local interconnect formed in a local interconnect layer, extending in the second direction, and being in contact with the second active region, and
the second active region is electrically connected to the second power line.

5. The semiconductor integrated circuit device of claim 1, comprising
a third nanosheet extending in the first direction on a boundary between the first standard cell and the second standard cell, the third nanosheet being contiguous with the first active region and the second active region, and
a third gate interconnect extending in the second direction and intersecting with the third nanosheet at right angles in planar view,
wherein
the third gate interconnect is electrically connected to the second power line.

6. The semiconductor integrated circuit device of claim 5, wherein
the third gate interconnect is electrically connected to the second power line through a metal interconnect extending in the first direction.

7. The semiconductor integrated circuit device of claim 1, wherein
the first and second power lines are formed in an interconnect layer provided in a first semiconductor chip in which the first and second active regions are formed.

8. The semiconductor integrated circuit device of claim 1, wherein
the first and second power lines are formed in an interconnect layer provided in a second semiconductor chip bonded to a back of a first semiconductor chip in which the first and second active regions are formed.

9. A semiconductor integrated circuit device, comprising
a plurality of cell rows each including a plurality of standard cells arranged in a first direction,
wherein
the plurality of cell rows include
a first cell row, and
a second cell row located on an end of the plurality of cell rows in a second direction perpendicular to the first direction, and adjoining the first cell row,
the first cell row includes a first standard cell having a logical function,
the second cell row includes a second standard cell located adjacent to the first standard cell and having no logical function,
the first standard cell includes
a first active region forming a channel, source, and drain of a first transistor of a first conductivity type, and including a first nanosheet extending in the first direction as the channel,
a first gate interconnect extending in the second direction and intersecting with the first nanosheet at right angles in planar view, and
a first power line formed on a back side of the first transistor, extending in the first direction, having an overlap with the first active region in planar view, and supplying a first power supply voltage,
the second standard cell includes
a second active region including a second nanosheet extending in the first direction,
a second gate interconnect extending in the second direction and intersecting with the second nanosheet at right angles in planar view, and
a second power line formed in a same interconnect layer as the first power line, extending in the first direction, having an overlap with the second active region in planar view, and supplying the first power supply voltage,
the second nanosheet is the same in width in the second direction and a distance from a boundary between the first standard cell and the second standard cell as the first nanosheet, and
the second power line is the same in width in the second direction as the first power line.

10. The semiconductor integrated circuit device of claim 9, wherein
the second gate interconnect is the same in length in the second direction and position in the first direction as the first gate interconnect.

11. The semiconductor integrated circuit device of claim 9, wherein
the first and second power lines are formed in an interconnect layer provided in a first semiconductor chip in which the first and second active regions are formed.

12. The semiconductor integrated circuit device of claim 9, wherein
the first and second power lines are formed in an interconnect layer provided in a second semiconductor chip bonded to a back of a first semiconductor chip in which the first and second active regions are formed.
